(19) United States
(12) Patent Application Publication
(10) Pub. No.: US 2026/0047286 A1
(43) Pub. Date: Feb. 12, 2026

(54) DISPLAY PANEL, DISPLAY APPARATUS, AND TERMINAL DEVICE

(71) Applicants: Ordos Yuansheng Optoelectronics Co., Ltd., Ordos, Inner Mongolia (CN); BOE TECHNOLOGY GROUP CO., LTD., Beijing (CN)

(72) Inventor: Pengfu YU, Beijing (CN)

(73) Assignees: Ordos Yuansheng Optoelectronics Co., Ltd., Ordos, Inner Mongolia (CN); BOE TECHNOLOGY GROUP CO., LTD., Beijing (CN)

(21) Appl. No.: 19/100,590

(22) PCT Filed: Oct. 31, 2023
(86) PCT No.: PCT/CN2023/128112

§ 371 Date: Feb. 3, 2025

(30) Foreign Application Priority Data
Nov. 25, 2022 (CN) 202211496996.0

(51) Int. Cl. H10K 59/131; H10K 59/121

(52) U.S. Cl. CPC H10K 59/131; H10K 59/1213

(57) ABSTRACT

A display panel has a display area and a peripheral area outside the display area, and the peripheral area has a fan-out area extending to a direction away from the display area and having a binding area. The display panel includes: a driving backplane including a substrate, a circuit layer disposed on a side of the substrate, and a plurality of bonding pads in the binding area, one of the bonding pads including a first bonding sub-pad and a second bonding sub-pad, the first bonding sub-pad being disposed on a side of the substrate away from the circuit layer, the second bonding sub-pad being disposed on a side of the substrate away from the first bonding sub-pad and overlapping with the first bonding sub-pad; and a light-emitting device disposed on a side of the circuit layer away from the substrate and located in the display area.

### CROSS-REFERENCE TO RELATED APPLICATION

This disclosure claims priority to Chinese Patent Application No. 202211496996.0, filed on Nov. 25, 2022 and entitled “Display panel, Display Apparatus, and Terminal Device”, the entire content of which is incorporated herein by reference in its entirety.

### TECHNICAL FIELD

This disclosure relates to the field of display technology and, more particularly, to a display panel, a display apparatus, and a terminal device.

### BACKGROUND

Display panels have become an indispensable part of terminal devices such as mobile phones, tablets, and televisions. The display panels using organic light-emitting diodes (OLEDs) are widely adopted. However, the existing display panels have a relatively wide bezel, resulting in a lower screen-to-body ratio, which is not conducive to improving resolution.

It should be noted that information disclosed in the Background is only used to acquire a better understanding of the background of this disclosure and therefore may include information that does not constitute the related art already known to those skilled in the art.

### SUMMARY

This disclosure provides a display panel, a display apparatus, and a terminal device, which can improve the screen-to-body ratio while ensuring electrical conductivity.

According to an aspect of this disclosure, there is provided a display panel having a display area and a peripheral area outside the display area, the peripheral area having a fan-out area extending to a direction away from the display area, and the fan-out area having a binding area. The display panel includes:
a driving backplane, including a substrate, a circuit layer, and a plurality of bonding pads in the binding area, in which the circuit layer is disposed on a side of the substrate; one of the bonding pads includes a first bonding sub-pad and a second bonding sub-pad connected to each other; the first bonding sub-pad is disposed on a side of the substrate away from the circuit layer; the second bonding sub-pad is disposed on a side of the substrate away from the first bonding sub-pad and overlapping with the first bonding sub-pad; and
a light-emitting device disposed on a side of the circuit layer away from the substrate and located in the display area.

In an exemplary embodiment of the present disclosure, the driving backplane is provided with a contact hole penetrating the substrate, and the first bonding sub-pad and the second bonding sub-pad are connected through the contact hole.

In an exemplary embodiment of the present disclosure, boundaries of orthogonal projections of the first bonding sub-pad and the second bonding sub-pad on the substrate coincide.

In an exemplary embodiment of the present disclosure, the circuit layer includes a semiconductor layer, a first gate insulating layer, a first gate layer, a second gate insulating layer, a second gate layer, an interlayer dielectric layer, a first source-drain layer, a first planarization layer, a second source-drain layer, and a second planarization layer sequentially stacked in a direction away from the substrate;

the second bonding sub-pad includes a first conductive layer and a second conductive layer sequentially stacked in the direction away from the substrate, the first conductive layer being disposed in a same layer as one of the first gate layer and the second gate layer, and the second conductive layer being disposed in a same layer as one of the first source-drain layer and the second source-drain layer.

In an exemplary embodiment of the present disclosure, a material of the first bonding sub-pad is identical to a material of the first conductive layer.

In an exemplary embodiment of the present disclosure, the substrate includes a first base and a second base arranged in a stacked manner; the circuit layer is partially disposed on a side of the second base away from the first base; and the second bonding sub-pad and the second base are disposed on a same side surface of the first base.

In an exemplary embodiment of the present disclosure, the display panel further includes:
an insulating layer disposed on the side of the substrate away from the first bonding sub-pad and at least partially located in the fan-out area, the insulating layer exposing the second bonding sub-pad.

In an exemplary embodiment of the present disclosure, the display area and the fan-out area are distributed in a column direction; the bonding pads extend in the column direction; the bonding pads are spaced apart in a row direction; a length of each of the first bonding sub-pad and the second bonding sub-pad in the column direction is not greater than 200 μm.

In an exemplary embodiment of the present disclosure, the display panel further includes:
a plurality of support pillars disposed on a side of the light-emitting device away from the driving backplane and located in the display area;
a transparent cover plate disposed on a side of the support pillars away from the driving backplane; and
an adhesive adhering between the transparent cover plate and the substrate and located outside the display area, the bonding pads being located on a side of the adhesive away from the display area.

According to an aspect of this disclosure, there is provided a display apparatus, including:
the display panel according to any one of the above embodiments; and
a flexible circuit board lapped to the second bonding sub-pad, bent to a side of the substrate away from the light-emitting device, and lapped to the first bonding sub-pad, in which the flexible circuit board is configured to be connected to a control circuit board.

In an exemplary embodiment of the present disclosure, the flexible circuit board has a first binding portion, a second binding portion, and a third binding portion, as well as a first window exposing the first binding portion, a second window exposing the second binding portion, and a third window exposing the third binding portion;
the first bonding sub-pad is connected to the second binding portion through the second window, the second bonding sub-pad is connected to the first binding portion through the first window, and the third window is configured to connect the third binding portion to the control circuit board.

In an exemplary embodiment of the present disclosure, orthogonal projections of the first window and the second window on the substrate are smaller than an orthogonal projection of the third window on the substrate.

In an exemplary embodiment of the present disclosure, the flexible circuit board includes:
a flexible substrate;
a wiring layer disposed on a side of the flexible substrate, and including the first binding portion, the second binding portion, and the third binding portion; and
a protective layer covering the wiring layer, in which the first window, the second window, and the third window are in the protective layer.

In an exemplary embodiment of the present disclosure, the display apparatus further includes:
a support portion adhering between a peripheral surface of the substrate and the flexible circuit board.

According to an aspect of this disclosure, there is provided a terminal device, including: the display apparatus according to any one of the above embodiments; and
a control circuit board disposed on a side of the substrate away from the light-emitting device and connected to the flexible circuit board.

For the display panel, the display apparatus, and the terminal device according to this disclosure, the bonding pads may be divided into the first bonding sub-pad and the second bonding sub-pad that are interconnected and disposed on both sides of the substrate. Under the condition of the same conduction area, compared to the bonding pad entirely located on one side of the substrate, the length of the bonding pad in this disclosure may be smaller, which can reduce space occupied by the bonding pads in the peripheral area, decrease a width of the peripheral area, and improving the screen-to-body ratio.

It should be understood that the foregoing general description and the following detailed description are exemplary and explanatory only and are not restrictive of this disclosure.

### BRIEF DESCRIPTION OF THE DRAWINGS

The accompanying drawings, which are incorporated into and constitute a part of this specification, illustrate embodiments consistent with this disclosure and, together with the description, serve to explain the principles of this disclosure. It is evident that the drawings in the following description are only some embodiments of this disclosure. For those skilled in the art, other drawings may be derived from these drawings without creative effort.

FIG. 1 is a top view of an embodiment of a display panel according to this disclosure.

FIG. 2 is a partial sectional view of a display area in an embodiment of the display panel according to this disclosure.

FIG. 3 is a schematic view of an embodiment 1 of a display panel according to this disclosure.

FIG. 4 is a schematic view of the embodiment in FIG. 3 when a second bonding sub-pad is not formed.

FIG. 5 is a schematic view of another embodiment of a display panel according to this disclosure.

FIG. 6 is a schematic view of yet another embodiment of a display panel according to this disclosure.

FIG. 7 is a top view of an embodiment of a display apparatus according to this disclosure.

FIG. 8 is a schematic view of an embodiment of a display apparatus according to this disclosure.

FIG. 9 is a schematic view of another embodiment of a display apparatus according to this disclosure.

FIG. 10 is a top view of a flexible circuit board in an embodiment of a display apparatus according to this disclosure.

FIG. 11 is a sectional view of a flexible circuit board in an embodiment of a display apparatus according to this disclosure.

FIG. 12 is a schematic view of an embodiment of a terminal device according to this disclosure.

### DETAILED DESCRIPTION

Exemplary embodiments will be now described more fully with reference to the accompanying drawings. However, the exemplary embodiments can be embodied in a variety of forms and should not be construed as limiting the embodiments set forth herein. Instead, these embodiments are provided so that this disclosure will be thorough and complete, and the concepts of the exemplary embodiments will be fully given to those skilled in the art. Same reference numbers denote the same or similar structures in the figures, and thus the detailed description thereof will be omitted. In addition, the drawings are merely schematic illustrations of this disclosure, and are not necessarily drawn to scale.

Words such as “one,” “an/a,” “the” and “said” are used herein to indicate the presence of one or more elements/component parts/and others. Terms “including” and “having” have an inclusive meaning which means that there may be additional elements/component parts/and others in addition to the listed elements/component parts/and others. Terms “first,” “second” and “third” are used herein only as markers, and they do not limit the number of objects modified after them.

A row direction X and a column direction Y herein are two intersecting directions, and may be perpendicular to each other. In the accompanying drawings of the present disclosure, the row direction X is a horizontal direction and the column direction Y is a vertical direction, which are not limited thereto, however. As a display panel is rotated, actual orientations of the row direction X and the column direction Y may change.

Feature A “overlapping with” feature B herein means that an orthographic projection of feature A on a substrate at least partially overlaps with an orthographic projection of feature B on the substrate. Certainly, the orthographic projection may be an orthographic projection on any plane parallel to an extension direction of a drive backplane.

The feature A and the feature B “being in a same layer” herein refers to that the feature A and the feature B may be formed simultaneously, and they are discontinuous or continuous areas within a same film layer.

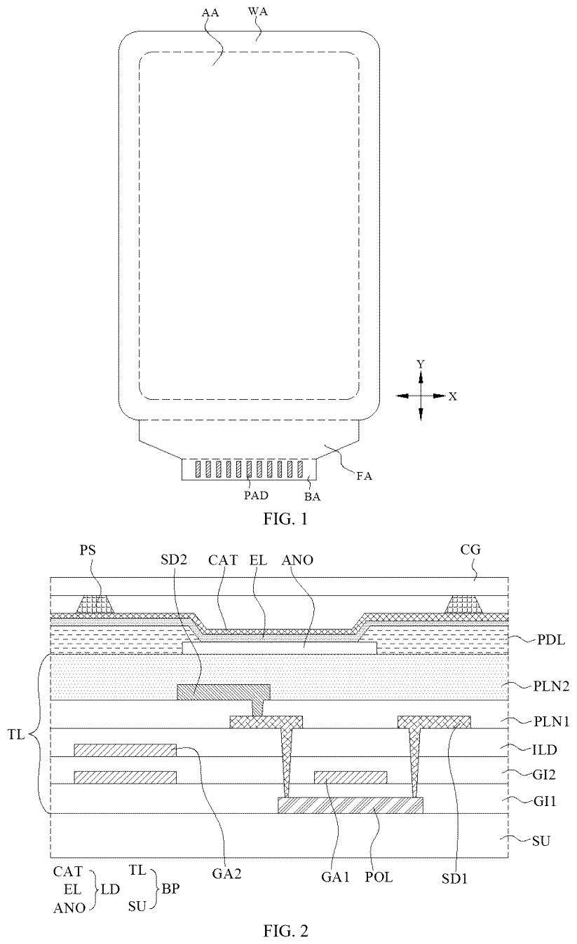

Embodiments of this disclosure provide a display panel, and as shown in FIG. 1, the display panel has a display area AA and a peripheral area WA located outside the display area AA. The peripheral area WA has a fan-out area FA extending in a direction away from the display area AA. The fan-out area FA has a binding area BA. As shown in FIG. 2, the display panel includes a driving backplane BP and a light-emitting device LD.

The driving backplane BP includes a substrate SU, a circuit layer TL, and a plurality of bonding pads PAD. The circuit layer TL is disposed on a side of the substrate SU. The bonding pads PAD are located in the binding area BA and are connected to the circuit layer TL. A bonding pad PAD includes a first bonding sub-pad PAD1 and a second bonding sub-pad PAD2 connected to each other. The first bonding sub-pad PAD1 is disposed on the side of the substrate SU away from the circuit layer TL. The second bonding sub-pad PAD2 is disposed on the side of the substrate SU away from the first bonding sub-pad PAD1 and overlaps with the first bonding sub-pad PAD1.

The light-emitting device LD is disposed on a side of the circuit layer TL away from the substrate SU and is located in the display area AA.

In the display panel according to the embodiment of this disclosure, the bonding pads PAD are divided into the first bonding sub-pad PAD1 and the second bonding sub-pad PAD2 connected to each other, and is disposed on both sides of the substrate SU. With the same conduction area, compared to the bonding pad PAD entirely located on the side of the substrate SU, a length of the bonding pad PAD of this disclosure may be small, which is beneficial for reducing the space occupied by the bonding pad PAD in the peripheral area WA, thereby reducing the width of the peripheral area WA and improving the screen-to-body ratio.

Hereinafter, the display panel of this disclosure will be described in detail.

As shown in FIG. 1, the display area AA of the display panel is a light-emitting area for displaying an image. The peripheral area WA is located outside the display area AA. For example, the peripheral area WA may be a continuous or discontinuous annular region surrounding the display area AA, or may be a semi-enclosed region such as a “U” shaped region. The shape of the peripheral area WA is not specifically limited herein.

The fan-out area FA extends in the direction away from the display area AA and may be distributed in a column direction Y with the display area AA. The fan-out area FA has a binding area BA, which may include a plurality of bonding pads PAD for binding with a flexible printed circuit (FPC).

The display area AA and the peripheral area WA are divided based on functions thereof, and it is not intended to limit the existence of a physical boundary for partitioning in the display panel.

The driving backplane BP includes a driving circuit for driving the light-emitting device LD to emit light. The driving circuit may include a pixel circuit located in the display area AA and a peripheral circuit located in the peripheral area WA.

There are a plurality of pixel circuits arranged in rows and in columns along the row direction X and the column direction Y. A pixel circuit may be connected to one light-emitting device LD. Certainly, there may also be cases where one pixel circuit is connected to a plurality of light-emitting devices LD. In this disclosure, an example of the pixel circuit and the light-emitting device LD being connected in one-to-one correspondence is taken. The pixel circuit may include transistors and capacitors, which may be pixel circuits such as a 3T1C, 7T1C, 8T1C, etc. nTmC represents that one pixel circuit includes n transistors (represented by “T”) and m capacitors (represented by “C”).

The peripheral circuit may be connected to the pixel circuit and the light-emitting device LD, and may control current passing through the light-emitting device LD via the pixel circuit, thereby controlling brightness of the light-emitting device LD. The peripheral circuit may include transistors and capacitors, which may include a gate electrode driving circuit and a light-emitting control circuit, etc. Certainly, the peripheral circuit may also include other circuits. The specific structure of the peripheral circuit is not specifically limited herein.

Hereinafter, film layers of the driving backplane BP will be exemplarily described.

As shown in FIG. 2, the driving backplane BP may include a substrate SU and a circuit layer TL.

The substrate SU may be a base of the driving backplane BP and may carry the pixel circuit and the peripheral circuit. The substrate SU may be a rigid or flexible structure and may have a single-layer or multi-layer structure, which is not specifically limited herein.

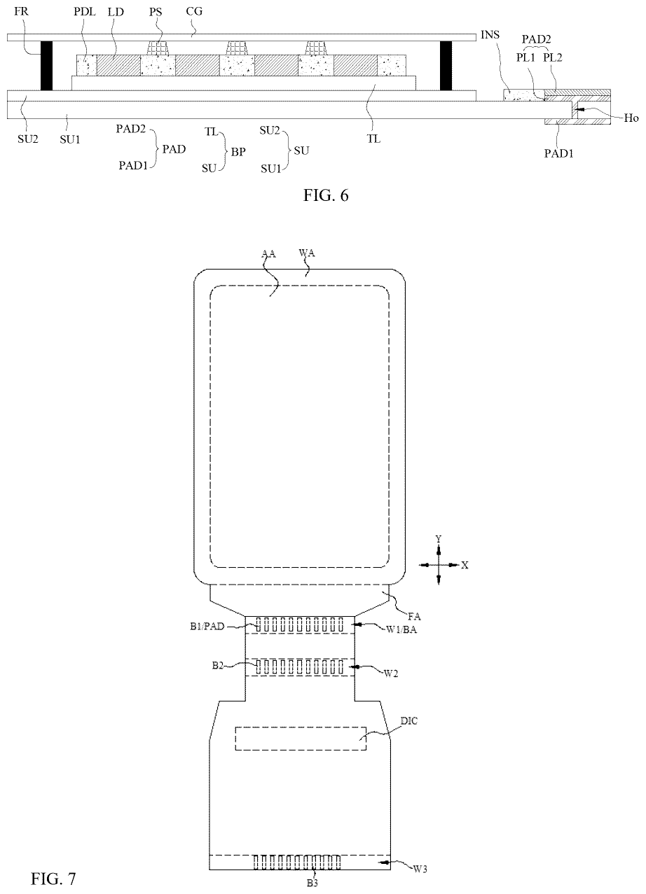

As shown in FIG. 6, in some embodiments of this disclosure, the substrate SU may include a first base SU1 and a second base SU2 stacked together. Both the first base SU1 and the second base SU2 may be made of glasses. A portion of the circuit layer TL is located on a side of the second base SU2 away from the first base SU1. The first base SU1 may extend from the display area AA to the peripheral area WA and further to the binding area BA. If a boundary of the first base SU1 may be a boundary of the display panel, the second base SU2 may not be provided in the binding area BA, that is, the second base SU2 is located outside the binding area BA. Additionally, a buffer layer or other film layers may be provided between the first base SU1 and the second base SU2.

As shown in FIG. 2, the circuit layer TL is disposed on the side of the substrate SU and may include transistors and capacitors of the driving circuit. In some embodiments of this disclosure, the transistor layer TF may include a semiconductor layer POL, a first gate insulating layer GI1, a first gate layer GA1, a second gate insulating layer GI2, a second gate layer GA2, an interlayer dielectric layer ILD, a first source-drain layer SD1, a first planarization layer PLN1, a second source-drain layer SD2, and a second planarization layer PLN2 sequentially stacked in a direction away from the substrate SU.

The semiconductor layer POL may be disposed on the side of the substrate SU, includes channels of the transistors, and may be made of polysilicon.

The first gate insulating layer GI1 may cover the semiconductor layer POL. The material of the first gate insulating layer GI1 may be an insulating material such as silicon nitride or silicon oxide.

The first gate layer GA1 may be disposed on a surface of the first gate insulating layer GI1 away from the substrate SU and includes gate electrodes of the transistors and a first electrode plate of the capacitor.

The second gate insulating layer GI2 may cover the first gate layer GA1, and the material thereof may be an insulating material such as silicon nitride or silicon oxide.

The second gate layer GA2 may be disposed on a surface of the second gate insulating layer GI2 away from the substrate SU and includes a second electrode plate of the capacitor. The second electrode plate overlaps with the first electrode plate to form the capacitor.

The interlayer dielectric layer ILD may cover the second gate layer GA2, and the material thereof may include inorganic insulating materials such as silicon nitride, silicon oxide, or silicon oxynitride, which is not specifically limited herein.

As shown in FIG. 2, the first source-drain layer SD1 may be disposed on a surface of the interlayer dielectric layer ILD away from the substrate SU. The first source-drain layer may have a single-layer or multi-layer structure, and its material may include one or more metals such as Ti, Al, Mg, or Ag. For example, the first source-drain layer SD1 may include a first sub-layer, a second sub-layer, and a third sub-layer sequentially stacked in the direction away from the substrate SU. The first sub-layer and the third sub-layer may be made of the same metal material, such as Ti, while the second sub-layer may be made of a metal material, such as Al different the first sub-layer and the third sub-layer.

The first planarization layer PLN1 may be disposed on a side of the first source-drain layer SD1 away from the substrate SU, and the material thereof may be an insulating material such as resin. Additionally, the display panel may further include a passivation layer covering the first source-drain layer SD1. The first planarization layer PLN1 covers the passivation layer. Alternatively, the first planarization layer PLN1 may directly cover the first source-drain layer SD1.

The second source-drain layer SD2 may be disposed on a surface of the first planarization layer PLN1 away from the substrate SU, may have a single-layer or multi-layer structure, and the material thereof may include one or more metals such as Ti, Al, Mg, or Ag. For example, the second source-drain layer SD2 may have the same three-layer structure as the first source-drain layer SD1.

The second planarization layer PLN2 may cover the second source-drain layer SD2, and the material thereof may be an insulating material such as resin.

The driving backplane BP further includes a plurality of bonding pads PAD connected to the driving circuit. The bonding pads PAD may be input and output pins of the driving circuit. Each bonding pad PAD is located within the binding area BA and may be spaced apart in the row direction X and extend in the column direction Y.

As shown in FIG. 2, each light-emitting device LD may be disposed on a side of the circuit layer TL away from the substrate SU. For example, the light-emitting device LD may be disposed on a surface of the second planarization layer PLN2 away from the substrate SU. Each light-emitting device LD is located within the display area AA. The light-emitting device LD may be an OLED (organic light-emitting diode), or may be a Micro LED (micro light-emitting diode), a Mini LED (sub-millimeter light-emitting diode), or a QLED (quantum dot diode), etc.

For example, the light-emitting device LD may include a first electrode ANO, a light-emitting layer EL, and a second electrode CAT sequentially stacked in a direction away from the driving backplane BP. The first electrode ANO may be disposed on a side of the driving backplane BP and arranged in an array. For example, the first electrode ANO may be disposed on a surface of the second planarization layer PLN2 away from the substrate SU. The first electrode ANO is connected to the pixel circuit. The light-emitting layer EL may include a hole injection layer, a hole transport layer, a light-emitting material layer, an electron transport layer, and an electron injection layer sequentially stacked in a direction away from the driving backplane BP. The second electrode CAT may be shared by all light-emitting devices LD, that is, the second electrode CAT may be a continuous entire-layer structure.

Furthermore, as shown in FIG. 2, in order to define a light-emitting range of the light-emitting device LD and prevent crosstalk, a pixel definition layer PDL may be disposed on a surface where the first electrode ANO is disposed. The pixel definition layer PDL is located within the display area AA and is provided with openings exposing the first electrodes ANO. The light-emitting layer EL is stacked with the first electrode ANO within the openings. For example, both the pixel definition layer PDL and the first electrode ANO may be disposed on a surface of the second planarization layer PLN2 away from the substrate SU. The openings of the pixel definition layer PDL may be smaller than the exposed first electrode ANO. Since the light-emitting layer EL is an entire-layer structure, it not only stacks with the first electrode ANO within the openings but also covers the pixel definition layer PDL.

The light-emitting material layers of the light-emitting devices LD are spaced apart, to allow the light-emitting devices LD to directly emit monochromatic light. The light-emitting devices LD have different light-emitting colors, in order to display colors. Alternatively, the light-emitting material layers of all light-emitting devices LD may form a continuous entire-layer structure, resulting in the same light-emitting color for all light-emitting devices LD. In this case, a light-filtering layer (color filter layer) CFL located on the side of the light-emitting device LD away from the driving backplane BP can display colors.

Furthermore, as shown in FIGS. 2, 3-6, in some embodiments of this disclosure, the display panel may also include support pillars PS and a transparent cover plate CG.

There are a plurality of support pillars PS, which may be arranged in an array on a side of the light-emitting device LD away from the driving backplane BP. At least a portion of the support pillars PS is located within the display area AA. The support pillars PS may be directly disposed on a surface of the pixel definition layer PDL away from the substrate SU. The second electrode CAT covers the support pillars PS and protrudes at positions corresponding to the support pillars PS. Alternatively, the support pillars PS may be disposed on a surface of the second electrode CAT away from the substrate SU.

The transparent cover plate CG may be made of a transparent rigid material such as glass or acrylic, and may be supported on a side of the support pillars PS away from the driving backplane BP. For example, the transparent cover plate CG may be placed on the second electrode CAT lifted by the support pillars PS and may directly contact the support pillars PS disposed on a surface of the second electrode CAT away from the substrate SU.

Further, as shown in FIGS. 3-6, the transparent cover plate CG and the substrate SU may be bonded outside the display area AA by using an adhesive FR. The adhesive FR may have a ring-shaped structure. The bonding of the transparent cover plate CG and the substrate SU via the adhesive FR can encapsulate the light-emitting devices LD within the display area AA, to prevent external moisture and oxygen from damaging the light-emitting devices LD. The bonding pads PAD may be located on a side of the adhesive FR away from the display area AA. For example, the adhesive FR may be disposed on a surface of the second base SU2 away from the first base SU1. The bonding pads PAD do not extend into an area enclosed by the adhesive FR, to prevent damaging the support pillars PS when the flexible printed circuit (FPC) is pressed and bonded to the bonding pads PAD.

The material of the adhesive FR may be a frit glue, which may be a mixture of glass powder and solvent, after laser sintering, to be melted to achieve a sealed bond. Additionally, an inert gas may be filled into a space enclosed by the transparent cover plate CG, the substrate SU, and the adhesive FR.

Hereinafter, the structure of the bonding pad PAD will be described in detail.

As shown in FIGS. 3-6, the bonding pad PAD may include a first bonding sub-pad PAD1 and a second bonding sub-pad PAD2. The first bonding sub-pad PAD1 may be located on a side of the substrate SU away from the circuit layer TL, while the second bonding sub-pad PAD2 may be located on a side of the substrate SU away from the first bonding sub-pad PAD2. The second bonding sub-pad PAD2 may be connected to the driving circuit of the circuit layer TL. The first bonding sub-pad PAD1 and the second bonding sub-pad PAD2 on the same bonding pad PAD are arranged in an overlapping manner, that is, orthographic projections of the first bonding sub-pad PAD1 and the second bonding sub-pad PAD2 on the substrate SU at least partially overlap. For example, boundaries of the orthographic projections of the first bonding sub-pad PAD1 and the second bonding sub-pad PAD2 on the substrate SU may coincide, so that the boundaries of the first bonding sub-pad PAD1 and the second bonding sub-pad PAD2 are aligned in a direction perpendicular to the substrate SU, with a length ratio of 1:1 in the column direction Y.

The length of each of the first bonding sub-pad PAD1 and the second bonding sub-pad PAD2 in the column direction Y may be no greater than 200 μm. This can minimize the length of the bonding pad PAD in the column direction Y while ensuring conductivity, which can help narrow the binding area and improve the screen-to-body ratio.

In some embodiments of this disclosure, the lengths of the first bonding sub-pad PAD1 and the second bonding sub-pad PAD2 on the same bonding pad PAD in the column direction Y may be different, resulting in only partial overlap of their orthographic projections on the substrate SU. For example, the length of the first bonding sub-pad PAD1 in the column direction Y may be greater than that of the second bonding sub-pad PAD2, causing the orthographic projection of the second bonding sub-pad PAD2 on the substrate SU to lie within that of the first bonding sub-pad PAD1. Alternatively, the length of the second bonding sub-pad PAD2 in the column direction Y may be greater than that of the first bonding sub-pad PAD1 in the column direction Y.

Additionally, a length, in the column direction Y, of a projection after the orthographic projections of the first bonding sub-pad PAD1 and the second bonding sub-pad PAD2 on the substrate SU overlap, may be less than 400 μm, and meanwhile, a length of one of the first bonding sub-pad PAD1 and the second bonding sub-pad PAD2 in the column direction Y may be greater than 200 μm. A length ratio of the first bonding sub-pad PAD1 to the second bonding sub-pad PAD2 in the column direction Y may be greater than or less than 1:1.

In some embodiments of this disclosure, the lengths of the first bonding sub-pad PAD1 and the second bonding sub-pad PAD2 of the same bonding pad PAD in the column direction Y may be the same, but the orthographic projections of the first bonding sub-pad PAD1 and the second bonding sub-pad PAD2 on the substrate SU may only partially overlap, that is, the first bonding sub-pad PAD1 and the second bonding sub-pad PAD2 may be offset in the column direction Y.

A length, in the column direction Y, of a projection after the orthographic projections of the first bonding sub-pad PAD1 and the second bonding sub-pad PAD2 on the substrate SU overlap, may be less than 400 μm. Meanwhile, the length of one of the first bonding sub-pad PAD1 and the second bonding sub-pad PAD2 in the column direction Y may be not greater than 200 μm. The length ratio of the first bonding sub-pad PAD1 to the second bonding sub-pad PAD2 in the column direction Y may be 1:1.

In some embodiments of this disclosure, in order to achieve the connection between the first bonding sub-pad PAD1 and the second bonding sub-pad PAD2, a contact hole Ho penetrating the substrate SU may be formed in the driving backplane BP. The first bonding sub-pad PAD1 and the second bonding sub-pad PAD2 may be connected through the contact hole Ho, thereby forming the bonding pad PAD.

As shown in FIGS. 3-6, in an embodiment, the first bonding sub-pad PAD1 may be disposed on a surface of the substrate SU away from the circuit layer TL, and the second bonding sub-pad PAD2 may be disposed on a surface of the substrate SU away from the first bonding sub-pad PAD1. The substrate SU is provided with a contact hole Ho to connect the first bonding sub-pad PAD1 and the second bonding sub-pad PAD2.

In an embodiment, the second bonding sub-pad PAD2 and the second base SU2 may be disposed on a same side surface of the first base SU1, and the first bonding sub-pad PAD1 may be disposed on a surface of the first base SU1 away from the second bonding sub-pad PAD2.

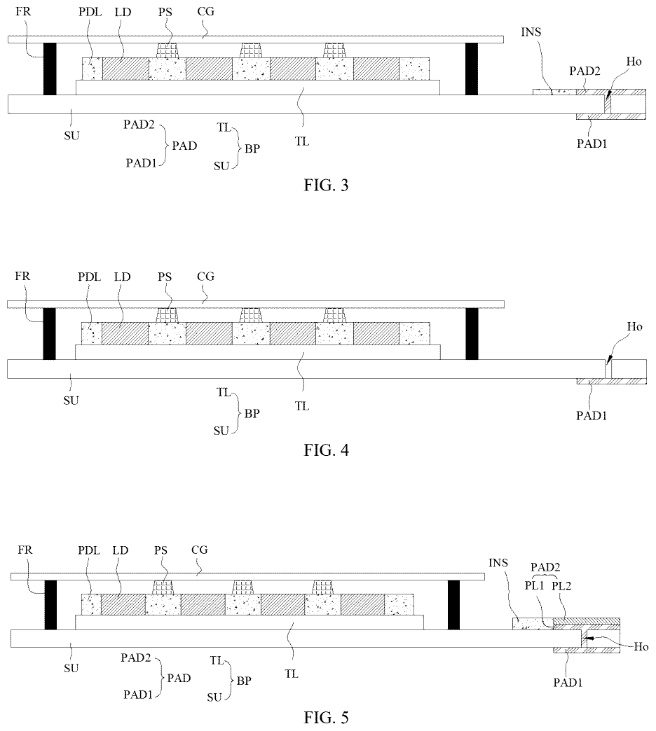

As shown in FIG. 4, when forming the first bonding sub-pad PAD1 and the second bonding sub-pad PAD2, the first bonding sub-pad PAD1 may first be formed on the side of the substrate SU, as shown in FIG. 4. Secondly, the contact hole Ho exposing the first bonding sub-pad PAD1 is formed in the substrate SU, as shown in FIG. 3. Subsequently, the second bonding sub-pad PAD2 is formed to cover the contact hole Ho, and the second bonding sub-pad PAD2 is connected to the first bonding sub-pad PAD1 through the contact hole.

In order to ensure consistent conductivity between the first bonding sub-pad PAD1 and the second bonding sub-pad PAD2, they may include the same materials. For example, the first bonding sub-pad PAD1 and the second bonding sub-pad PAD2 may contain metals such as molybdenum or copper, or may include alloys or metal oxides, as long as they are conductive.

In order to simplify the process, the second bonding sub-pad PAD2 may be formed simultaneously with some conductive layers in the circuit layer TL.

As an example, as shown in FIGS. 5 and 6, in some embodiments of this disclosure, the second bonding sub-pad PAD2 may include a first conductive layer PL1 and a second conductive layer PL2 sequentially stacked in the direction away from the substrate SU. The first conductive layer PL1 may be formed on the same layer as one of the first gate layer GA1 or the second gate layer GA2, allowing the first conductive layer PL1 to be formed while forming the first gate layer GAL or the second gate layer GA2. Meanwhile, the second conductive layer PL2 may be formed on the same layer as one of the first source-drain layer SD1 and the second source-drain layer SD2, so that the second conductive layer PL2 is formed while the first source-drain layer SD1 or the second source-drain layer SD2 is formed. If the first source-drain layer SD1 and the second source-drain layer SD2 are multi-layer structures, the second conductive layer PL2 will also have the same multi-layer structure. For example, the second conductive layer PL2 may include three conductive sub-layers, each formed on the same layer as the corresponding sub-layers of the second source-drain layer SD2.

Furthermore, the first bonding sub-pad PAD1 is connected to the first conductive layer PL1 of the second bonding sub-pad PAD2. The material of the first bonding sub-pad PAD1 may be the same as that of the first conductive layer PL1 to ensure the consistent conductivity between them.

As shown in FIGS. 3, 5, and 6, in some embodiments of this disclosure, the display panel may further include an insulating layer INS, which may be disposed on a side of the substrate SU away from the first bonding sub-pad PAD1 and at least partially located in the fan-out area FA. The insulating layer INS is provided with connection holes exposing the second bonding sub-pad PAD2. As connecting to the flexible printed circuit (FPC), the FPC may be stacked on the insulating layer INS and connected through conductive adhesive ACF filled into the connection holes. The conductive adhesive ACF may be anisotropic conductive film (ACF), which has a conductivity in an axial direction of the connection hole greater than a conductivity in the radial direction of the connection hole.

The insulating layer INS may have a single-layer or multi-layer structure and may be formed on the same layer as some insulating layers in the circuit layer TL to simplify the process. For example, the insulating layer INS may be formed on the same layer as the second planarization layer PLN2.

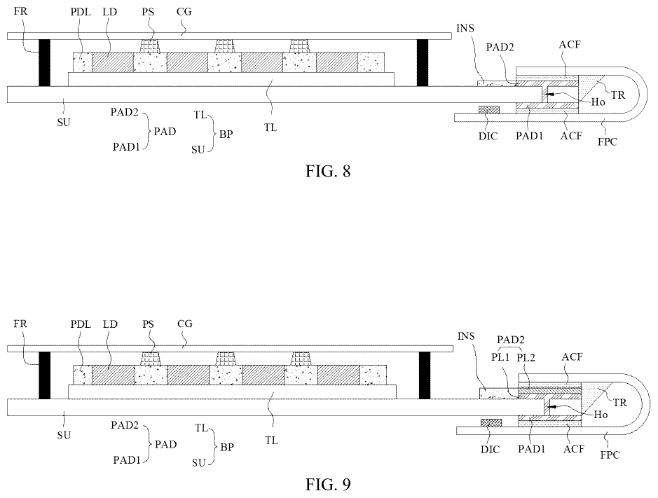

This disclosure also provides a display apparatus. As shown in FIGS. 7-9, the display apparatus may include a display panel and a flexible printed circuit (FPC).

The display panel may be the display panel described in any of the above embodiments, and its structure will not be detailed here.

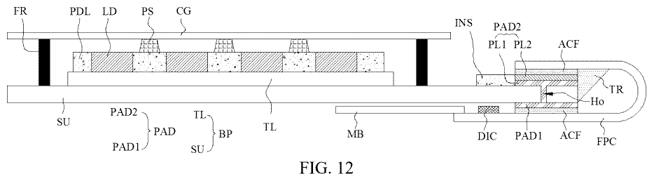

As shown in FIGS. 7-9 and FIG. 12, the FPC may be lapped to the second bonding sub-pad PAD2 and bent to a side of the substrate SU away from the light-emitting device LD. The FPC may also be lapped to the first bonding sub-pad PAD1 and connected to a control circuit board MB, enabling the display panel to display images under the control of the control circuit board MB.

In some embodiments of this disclosure, the FPC includes a first binding portion, a second binding portion, and a third binding portion. The FPC may have a first window W1 exposing the first binding portion, a second window W2 exposing the second binding portion, and a third window W3 exposing the third binding portion. The first bonding sub-pad PAD1 may be connected to the second binding portion through the second window W2, the second bonding sub-pad PAD2 may be connected to the first binding portion through the first window W1, and the third binding portion may be connected to the control circuit board MB through the third window W3.

The first binding portion may have the same size and shape as the second bonding sub-pad PAD2, and the second binding portion may have the same shape and size as the first bonding sub-pad PAD1. The third binding portion may be larger than the first and second binding portions. When the FPC is connected to the second bonding sub-pad PAD2 but not bent, the first window W, the second window W2, and the third window W3 may be distributed in the column direction Y. An orthographic projection of the first window W on the substrate SU and an orthographic projection of the second window W2 on the substrate SU are smaller than an orthographic projection of the third window W3 on the substrate SU. For example, the lengths of the first window W, the second window W2, and the third window W3 in the row direction X may be equal, while the widths of the first window W and the second window W2 in the column direction Y may be half the width of the third window W3 in the column direction Y. Additionally, the lengths of the first and second binding portions in the column direction Y may be half the length of the third binding portion in the column direction Y.

Further, the first binding portion may include first pins B1 corresponding one-to-one with second bonding sub-pad PAD2. The first window W1 may simultaneously expose all first pins B1, or there may be a plurality of first windows W1, each exposing a corresponding first pin B1.

The second binding portion may include second pins B2 corresponding one-to-one with the first bonding sub-pads PAD1. The second window W2 may simultaneously expose all second pins B2, or there may be a plurality of second windows W2, each exposing a corresponding second pin B2.

The third binding portion may include a plurality of third pins B3. The third window W3 may simultaneously expose all third pins B3, or there may be a plurality of third windows W3, each exposing a corresponding third pin B3. The pins of the control circuit board MB may be connected with the third pins B3 in one-to-one correspondence.

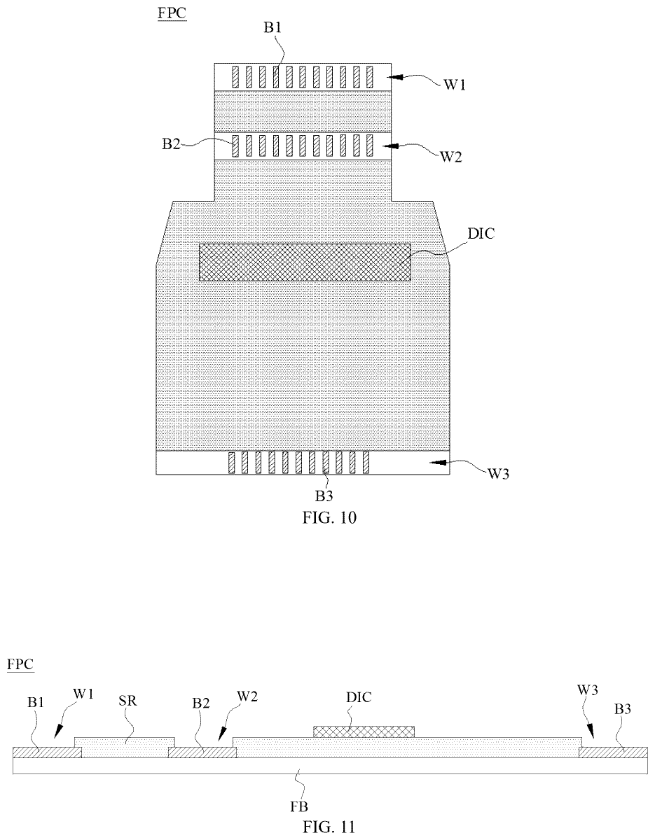

As shown in FIGS. 10 and 11, in some embodiments of this disclosure, the FPC includes a flexible substrate FB, a wiring layer LL, and a protective layer SR.

The flexible substrate FB may be made of a flexible material such as polyimide to allow bending.

The wiring layer LL may be disposed on a side of the flexible substrate FB and include the first binding portion, second binding portion, and third binding portion as aforementioned. The specific pattern of the wiring layer LL is not limited here. The wiring layer LL may have a single-layer or multi-layer structure and may include metals such as copper, alloys, or metal oxides, as long as it is conductive.

The protective layer SR may cover the wiring layer LL and be made of an insulating material. The first window W1, the second window W2, and the third window W3 are all disposed in a protective layer SR to expose the first binding portion, second binding portion, and third binding portion.

Additionally, in some embodiments of this disclosure, the display apparatus further includes a support portion TR, which may be adhering between an outer peripheral surface of the substrate SU and the bent FPC. The support portion TR may support the FPC and prevent the bent area of the FPC from being scratched by the substrate SU. The material of the support portion TR may be a sealant or the like.

Furthermore, in some embodiments of this disclosure, the display apparatus may also include a driver chip DIC, which may be disposed on the FPC and connected to the wiring layer LL. The driver chip DIC may be configured to drive the display panel to display images under the control of the control circuit board MB. After the FPC is bent to the side of the substrate SU away from the circuit layer TL, the driver chip DIC is located on the side of the substrate SU away from the circuit layer TL and may be located between the second window W2 and the third window W3.

Certainly, in other embodiments of this disclosure, the driver chip DIC may also be disposed on the driving backplane BP.

When the FPC is connected to the display panel, the first pins B1 of the first binding portion of the FPC may first be connected to the second bonding sub-pad PAD2 via the conductive adhesive ACF for pre-binding; and then the back adhesive is applied to the side of the substrate SU away from the circuit layer TL; subsequently, the FPC is bent; the first bonding sub-pads PAD1 are connected to the second pins B2 of the second binding portion via the conductive adhesive ACF for pre-binding; and finally, main binding is performed. The aforementioned pre-binding and main binding refer to processes such as light exposure or heating of the conductive adhesive ACF to achieve curing. The difference between pre-binding and the main binding is that the light intensity and heating temperature during pre-binding are less than that during the main binding, primarily to improve work efficiency.

This disclosure also provides a terminal device, which may include a display apparatus and a control circuit board MB.

The display apparatus may adopt the display apparatus described in any of the above embodiments, and its structure can refer to the embodiments of the display panel and display apparatus described above, which will not be detailed here.

The control circuit board MB may be disposed on the side of the substrate SU away from the light-emitting device LD and connected to the FPC. For example, the control circuit board MB may be connected to the third binding portion of the FPC via the conductive adhesive.

The terminal device of this disclosure may be mobile phones, tablet computers, head-mounted display devices, etc., which will not be listed here. The control circuit board MB may be a mainboard of the terminal device.

Other embodiments of this disclosure will be apparent to those skilled in the art from consideration of the specification and practice of the invention disclosed here. This application is intended to cover any variations, uses, or adaptations of this disclosure following the general principles thereof and including common knowledge or conventional technical means in the art that is not disclosed herein. The specification and embodiments are considered to be merely exemplary, and the true scope and spirit of this disclosure is indicated by the appended claims.

1. A display panel, having a display area and a peripheral area outside the display area, the peripheral area having a fan-out area extending to a direction away from the display area, and the fan-out area having a binding area, wherein the display panel comprises:
a driving backplane, comprising a substrate, a circuit layer, and a plurality of bonding pads in the binding area, wherein the circuit layer is disposed on a side of the substrate: one of the bonding pads comprises a first bonding sub-pad and a second bonding sub-pad connected to each other: the first bonding sub-pad is disposed on a side of the substrate away from the circuit layer: the second bonding sub-pad is disposed on a side of the substrate away from the first bonding sub-pad and overlapping with the first bonding sub-pad; and
a light-emitting device disposed on a side of the circuit layer away from the substrate and located in the display area.

2. The display panel according to claim 1, wherein the driving backplane is provided with a contact hole penetrating the substrate, and the first bonding sub-pad and the second bonding sub-pad are connected through the contact hole.

3. The display panel according to claim 2, wherein boundaries of orthogonal projections of the first bonding sub-pad and the second bonding sub-pad on the substrate coincide.

4. The display panel according to claim 1, wherein the circuit layer comprises a semiconductor layer, a first gate insulating layer, a first gate layer, a second gate insulating layer, a second gate layer, an interlayer dielectric layer, a first source-drain layer, a first planarization layer, a second source-drain layer, and a second planarization layer sequentially stacked in a direction away from the substrate:
the second bonding sub-pad comprises a first conductive layer and a second conductive layer sequentially stacked in the direction away from the substrate, the first conductive layer being disposed in a same layer as one of the first gate layer and the second gate layer, and the second conductive layer being disposed in a same layer as one of the first source-drain layer and the second source-drain layer.

5. The display panel according to claim 1, wherein a material of the first bonding sub-pad is identical to a material of the first conductive layer.

6. The display panel according to claim 1, wherein the substrate comprises a first base and a second base arranged in a stacked manner: the circuit layer is partially disposed on a side of the second base away from the first base; and the second bonding sub-pad and the second base are disposed on a same side surface of the first base.

7. The display panel according to claim 1, wherein the display panel further comprises:
an insulating layer disposed on the side of the substrate away from the first bonding sub-pad and at least partially located in the fan-out area, the insulating layer exposing the second bonding sub-pad.

8. The display panel according to claim 3, wherein the display area and the fan-out area are distributed in a column direction: the bonding pads extend in the column direction: the bonding pads are spaced apart in a row direction; a length of each of the first bonding sub-pad and the second bonding sub-pad in the column direction is not greater than 200 μm.

9. The display panel according to claim 1, wherein the display panel further comprises:
a plurality of support pillars disposed on a side of the light-emitting device away from the driving backplane and located in the display area;
a transparent cover plate disposed on a side of the support pillars away from the driving backplane; and
an adhesive adhering between the transparent cover plate and the substrate and located outside the display area, the bonding pads being located on a side of the adhesive away from the display area.

10. A display apparatus, comprising:
a display panel according to having a display area and a peripheral area outside the display area, the peripheral area having a fan-out area extending to a direction away from the display area, and the fan-out area having a binding area, wherein the display panel comprises a driving backplane and a light-emitting device; the driving backplane comprises a substrate, a circuit layer, and a plurality of bonding pads in the binding area; the circuit layer is disposed on a side of the substrate; one of the bonding pads comprises a first bonding sub-pad and a second bonding sub-pad connected to each other; the first bonding sub-pad is disposed on a side of the substrate away from the circuit layer; the second bonding sub-pad is disposed on a side of the substrate away from the first bonding sub-pad and overlapping with the first bonding sub-pad; and the light-emitting device is disposed on a side of the circuit layer away from the substrate and located in the display area; and
a flexible circuit board lapped to the second bonding sub-pad, bent to a side of the substrate away from the light-emitting device, and lapped to the first bonding sub-pad, wherein the flexible circuit board is configured to be connected to a control circuit board.

11. The display apparatus according to claim 10, wherein the flexible circuit board has a first binding portion, a second binding portion, and a third binding portion, as well as a first window exposing the first binding portion, a second window exposing the second binding portion, and a third window exposing the third binding portion:
the first bonding sub-pad is connected to the second binding portion through the second window, the second bonding sub-pad is connected to the first binding portion through the first window, and the third window is configured to connect the third binding portion to the control circuit board.

12. The display apparatus according to claim 11, wherein orthogonal projections of the first window and the second window on the substrate are smaller than an orthogonal projection of the third window on the substrate.

13. The display apparatus according to claim 11, wherein the flexible circuit board comprises:
a flexible substrate;
a wiring layer disposed on a side of the flexible substrate, and comprising the first binding portion, the second binding portion, and the third binding portion; and
a protective layer covering the wiring layer, wherein the first window, the second window, and the third window are in the protective layer.

14. The display apparatus according to claim 10, wherein the display apparatus further comprises:
a support portion adhering between a peripheral surface of the substrate and the flexible circuit board.

15. A terminal device, comprising:
a display apparatus according to comprising a display panel and a flexible circuit board, wherein the display panel has a display area and a peripheral area outside the display area, the peripheral area having a fan-out area extending to a direction away from the display area, and the fan-out area having a binding area; the display panel comprises a driving backplane and a light-emitting device; the driving backplane comprises a substrate, a circuit layer, and a plurality of bonding pads in the binding area; the circuit layer is disposed on a side of the substrate; one of the bonding pads comprises a first bonding sub-pad and a second bonding sub-pad connected to each other; the first bonding sub-pad is disposed on a side of the substrate away from the circuit layer; the second bonding sub-pad is disposed on a side of the substrate away from the first bonding sub-pad and overlapping with the first bonding sub-pad; the light-emitting device is disposed on a side of the circuit layer away from the substrate and located in the display area; the flexible circuit board lapped to the second bonding sub-pad, bent to a side of the substrate away from the light-emitting device, and lapped to the first bonding sub-pad; and the flexible circuit board is configured to be connected to a control circuit board; and
a control circuit board disposed on a side of the substrate away from the light-emitting device and connected to the flexible circuit board.

16. The terminal device according to claim 15, wherein the driving backplane is provided with a contact hole penetrating the substrate, and the first bonding sub-pad and the second bonding sub-pad are connected through the contact hole.

17. The terminal device according to claim 16, wherein boundaries of orthogonal projections of the first bonding sub-pad and the second bonding sub-pad on the substrate coincide.

18. The terminal device according to claim 15, wherein the circuit layer comprises a semiconductor layer, a first gate insulating layer, a first gate layer, a second gate insulating layer, a second gate layer, an interlayer dielectric layer, a first source-drain layer, a first planarization layer, a second source-drain layer, and a second planarization layer sequentially stacked in a direction away from the substrate:
the second bonding sub-pad comprises a first conductive layer and a second conductive layer sequentially stacked in the direction away from the substrate, the first conductive layer being disposed in a same layer as one of the first gate layer and the second gate layer, and the second conductive layer being disposed in a same layer as one of the first source-drain layer and the second source-drain layer.

19. The terminal device according to claim 15, wherein a material of the first bonding sub-pad is identical to a material of the first conductive layer.

20. The terminal device according to claim 15, wherein the substrate comprises a first base and a second base arranged in a stacked manner; the circuit layer is partially disposed on a side of the second base away from the first base; and the second bonding sub-pad and the second base are disposed on a same side surface of the first base.
